(19) United States
(12) Patent Application Publication
(10) Pub. No.: US 2014/0102890 A1
(43) Pub. Date: Apr. 17, 2014

(54) SPUTTERING APPARATUS

(71) Applicants: YoungJae JUNG, Yongin-City (KR); Hun Jung YI, Yongin-City (KR); Eun-Ju SONG, Yongin-City (KR)

(72) Inventors: YoungJae JUNG, Yongin-City (KR); Hun Jung YI, Yongin-City (KR); Eun-Ju SONG, Yongin-City (KR)

(21) Appl. No.: 13/782,083

(22) Filed: Mar. 1, 2013

(30) Foreign Application Priority Data
Oct. 12, 2012 (KR) 10-2012-0113288

(51) Int. Cl. C23C 14/34

(52) U.S. Cl. CPC C23C 14/3407
USPC 204/298.12

(57) ABSTRACT

A sputtering apparatus includes a substrate, a sputtering target disposed to face the substrate and formed of a sputtering material to be deposited on the substrate, wherein the sputtering target collides with an ionized gas particle and the sputtering material is separated from the sputtering target by the collision of the ionized gas particle with the sputtering target is deposited on the substrate, a supporter that supports a lower surface and a side surface of the sputtering target, and an insulating cover that covers an upper surface of the supporter supporting the side surface of the sputtering target. The insulating cover includes a plurality of recesses recessed downwardly from an upper surface of the insulating cover and a plurality of protrusions protruding upwardly between the recesses.

### CROSS-REFERENCE TO RELATED APPLICATION

This U.S. non-provisional patent application claims priority under 35 U.S.C. §119 to Korean Patent Application No. 10-2012-0113288, filed on Oct. 12, 2012, the contents of which are hereby incorporated by reference.

### BACKGROUND

1. Field

Embodiments relate to a sputtering apparatus.

2. Description of the Related Art

A sputtering apparatus is used to deposit various materials on a substrate. For instance, various layers, e.g., a metal layer, a transparent conductive layer, a dielectric layer, etc., may be deposited on a substrate using the sputtering apparatus. The sputtering apparatus is used in a deposition process of flat panel displays, such as a liquid crystal display, an organic light emitting display, etc.

According to a sputtering method utilized by the sputtering apparatus, a rare gas (or inert gas), e.g., argon (Ar) gas, is injected into a vacuum chamber. The injected gas is ionized by plasma. The ionized gas collides with a sputtering target on which a material, to be deposited on the substrate, is disposed. Due to the collision between the ionized gas and the sputtering target, a sputtering material is separated from the sputtering target and then deposited on the substrate.

### SUMMARY

Embodiments are directed to a sputtering apparatus including a substrate, a sputtering target disposed to face the substrate and including a sputtering material to be deposited on the substrate, the sputtering target colliding with an ionized gas particle such that the sputtering material is separated from the sputtering target by the collision of the ionized gas particle and the sputtering target is deposited on the substrate, a supporter that supports a lower surface and a side surface of the sputtering target, an insulating cover that covers an upper surface of the supporter supporting the side surface of the sputtering target. The insulating cover includes a plurality of recesses recessed downwardly from an upper surface of the insulating cover and a plurality of protrusions protruding upwardly between the recesses.

The supporter may include a first supporter attached to the lower surface of the sputtering target to support the sputtering target, and a second supporter attached to the side surface and upper peripheral surfaces of the sputtering target to support the sputtering target, the insulating cover covering an upper surface of the second supporter.

The insulating cover may include a dielectric material.

An upper surface of each of the protrusions may have an area from about 68 mm² to about 1000 mm².

The protrusions may be arranged in a matrix form.

The protrusions may extend in a row direction to have a stripe shape.

An aspect ratio defined by a depth and a width of each of the recesses may be equal to or greater than 3.

The insulating cover may have a thickness of about 2 mm to about 20 mm, the thickness being a distance between a lower surface of the insulating cover and an upper surface of the insulating cover.

Each of the protrusions may have a concavo-convex pattern.

A root-mean-square roughness of the concavo-convex pattern may be greater than about 1 micrometer.

The sputtering apparatus may further include a power supply part that applies a negative voltage to the sputtering target, and a gas supply part that provides the gas particle, wherein the gas particle collides with an electron discharged from the sputtering target to be ionized and the ionized gas particle collides with the sputtering target.

### BRIEF DESCRIPTION OF THE DRAWINGS

Features will become apparent to those of ordinary skill in the art by describing in detail exemplary embodiments with reference to the attached drawings in which:

FIG. 1 is a view showing a sputtering apparatus according to an exemplary embodiment;

FIG. 2A is a partially enlarged view of a portion A shown in FIG. 1;

FIG. 2B is a partially enlarged view of a portion B shown in FIG. 2A;

FIGS. 3A and 3B are views showing various shapes of a protruding portion shown in FIG. 2A; and

FIG. 4 is a view showing an insulating cover according to another exemplary embodiment.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

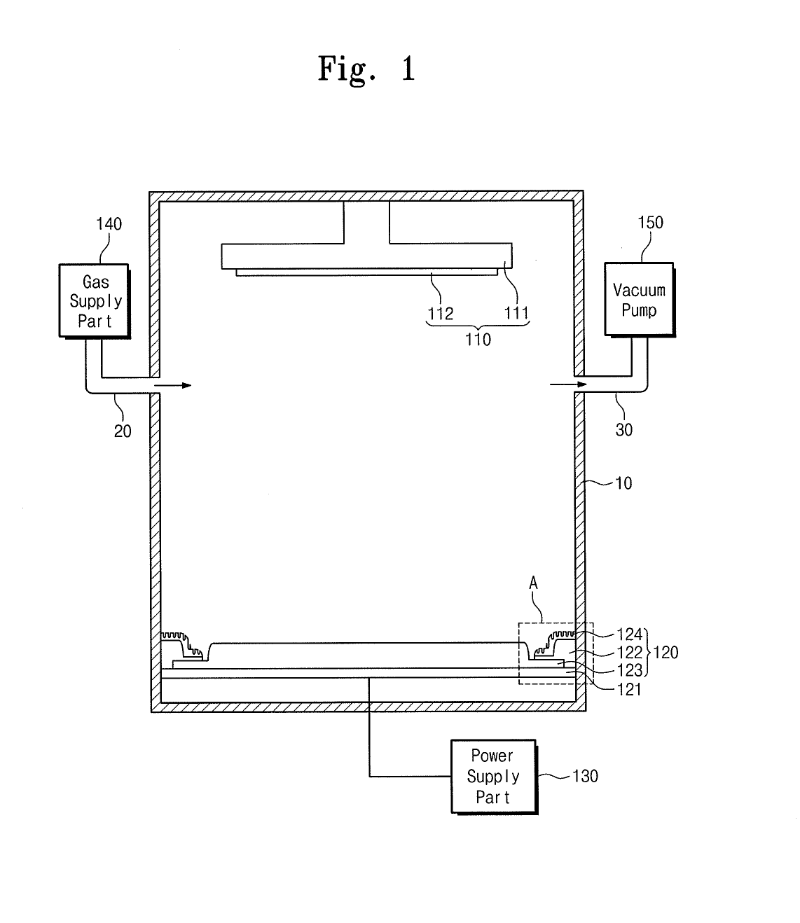

FIG. 1 is a view showing a sputtering apparatus according to an exemplary embodiment.

Referring to FIG. 1, a sputtering apparatus 100 includes a vacuum chamber 10, a substrate part 110, a target part 120, a power supply part 130, a gas supply part 140, and a vacuum pump 150.

The substrate part 110 is located at an upper position in the vacuum chamber 10. The target part 120 is located at a lower position in the vacuum chamber 10 to face a substrate. Although not shown in FIG. 1, the sputtering apparatus 100 further includes a target transfer part to transfer the target part 120.

The positions of the substrate part 110 and the target part 120 are not limited to the above-mentioned positions. For instance, the substrate part 110 and the target part 120 may be respectively located at the lower and upper positions in the vacuum chamber 10 as long as the substrate part 110 and the target part 120 face each other.

The substrate part 110 includes a substrate receiving part 111 and a substrate 112 disposed on the substrate receiving part 111.

The target part 120 includes a first supporter 121, a second supporter 122, a sputtering target 123 supported by the first and second supporters 121 and 122, and an insulating cover 124 disposed on the second supporter 122.

The sputtering target 123 is disposed to allow its upper surface to face the substrate 112. The sputtering target 123 is thinner at peripheral portions, such as the left and right portions illustrated in FIG. 1, than at a center portion thereof.

The sputtering target 123 is formed of a material to be deposited on the substrate 112. For instance, the sputtering target 123 may be formed of aluminum (Al), aluminum alloy, or equivalent material. In other implementations, the sputtering target 123 may be formed of indium tin oxide (ITO), indium zinc oxide (IZO), indium oxide (IO), zinc oxide (ZnO), tin zinc oxide (TZO), aluminum zinc oxide (AZO), gallium zinc oxide (GZO), etc.

The first supporter 121 is attached to a lower surface of the sputtering target 123 to support the sputtering target 123. The second supporter 122 is attached to a side surface and peripheral upper surfaces, such as left and right upper surfaces, of the sputtering target 123 to support the sputtering target 123.

The insulating cover 124 is disposed to cover the upper surface of the second supporter 122. The insulating cover 124 includes a plurality of recesses that are recessed downwardly from an upper surface thereof and a plurality of protrusions, each of which protrudes upwardly between the recesses. The insulating cover 124 may be formed of a dielectric material.

The power supply part 130 includes an RF (radio frequency) source or a DC (direct current) source. The power supply part 130 applies the RF source or the DC source to the sputtering target 123. The power supply part 130 is electrically connected to the sputtering target 123 through the first and second supporters 121 and 122. Accordingly, the power supply part 130 applies the source voltage to the sputtering target 123 through the first and second supporters 121 and 122.

The power supply part 130 applies a negative (−) voltage to the sputtering target 123 such that the sputtering target 123 serves as a cathode electrode. The vacuum chamber 10 serves as an anode electrode. The negative (−) voltage is applied to the sputtering target 123 through the first and second supporter 121 and 122.

The gas supply part 140 provides a rare gas, e.g., argon (Ar) gas, to the vacuum chamber 10 through a gas supply pipe 20. The gas supply part 140 may include an inert gas, such as argon, krypton, helium, or xenon. When those gases collide with the sputtering target 123, the sputtering material is separated from the sputtering target 123.

The gas supply part 140 includes a reactive gas, such as one or more oxygen-containing gases or nitrogen-containing gases. Those gases react with the sputtering material to allow a layer to be deposited on the substrate 112. That is, in a case that a material to be deposited on the substrate 112 is an oxide material containing oxygen atoms, the oxygen gas is provided into the vacuum chamber 10 in addition to the argon gas.

By-products and the used gases may be exhausted through an exhaust pipe 30 from the vacuum chamber 10. The exhaust pipe 30 is connected to the vacuum pump 150, e.g., a cryo-pump. The vacuum pump 150 maintains the inside of the vacuum chamber 10 in a low pressure vacuum state. For instance, the inner pressure of the vacuum chamber 10 may be maintained in a range from about 0.1 mTorr to about 100 mTorr by the vacuum pump 150.

When the negative (−) voltage is applied to the sputtering target 123 from the power supply part 130, electrons are discharged from the sputtering target 123. The electrons discharged from the sputtering target 123 collide with gas particles provided in the vacuum chamber 10. The gas particles are ionized by glow-discharge plasma generated due to the collision between the electrons and the gas particles. The ionized gas particles, e.g., positive-ion particles, are accelerated toward the sputtering target 123 and collide with the sputtering target 123. Due to the collision between the ionized gas particles and the sputtering target 123, the sputtering material is separated from the sputtering target 123 and then deposited on the substrate 112.

The dielectric substance is generated during the sputtering process. In detail, when the sputtering target 123 is formed of a dielectric substance to deposit a dielectric layer on the substrate 112, or when the sputtering target formed of a metal material, and oxygen gas is used in the sputtering process, the dielectric substance is generated.

The insulating cover 124 is disposed at the upper surface of the second supporter 122. Thus, the dielectric substance generated during the sputtering process is stacked onto the insulating cover 124 disposed on the second supporter 122.

As described above, the insulating cover 124 is formed of the dielectric substance. The insulating cover 124 formed of the dielectric substance may be the same material as the dielectric substance generated during the sputtering process and stacked on the insulating cover 124.

If the insulating cover 124 were to be formed of a material different from the dielectric substance generated during the sputtering process, the dielectric substance could have a thermal expansion rate different from that of the insulating cover 124. In this case, the dielectric substance stacked on the insulating cover 124 could be dropped onto the sputtering target 123.

The insulating cover 124 may be formed of the dielectric substance. Accordingly, the dielectric substance generated during the sputtering process may have the same thermal expansion rate as that of the insulating cover 124. When the dielectric substance generated during the sputtering process and the insulating cover 124 have the same thermal expansion rate, the dielectric substance stacked on the insulating cover 124 may be prevented from being dropped onto the sputtering target 123 or the occurrence of such may be reduced.

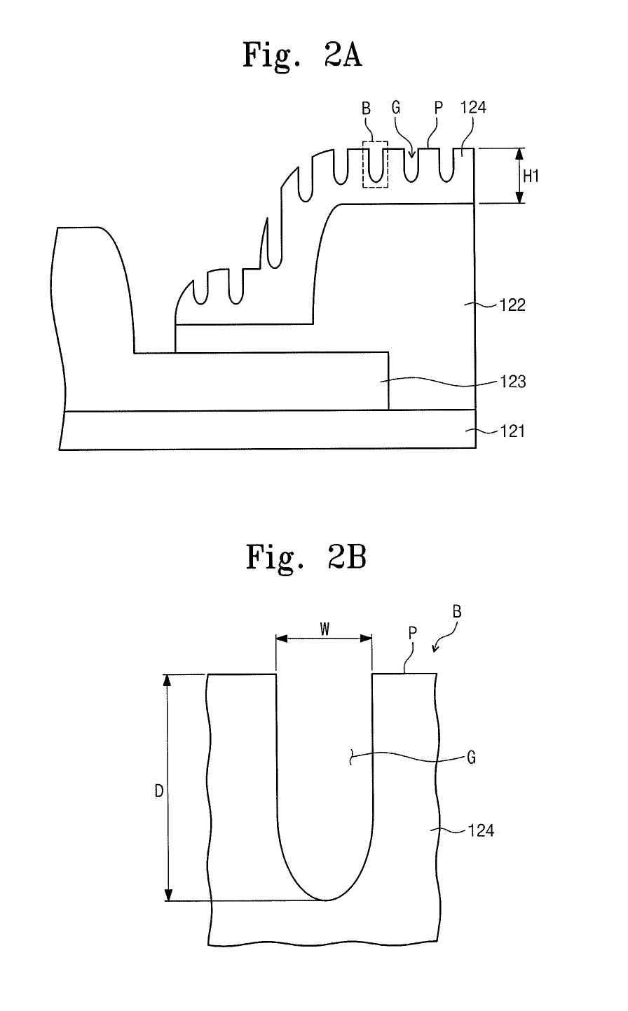

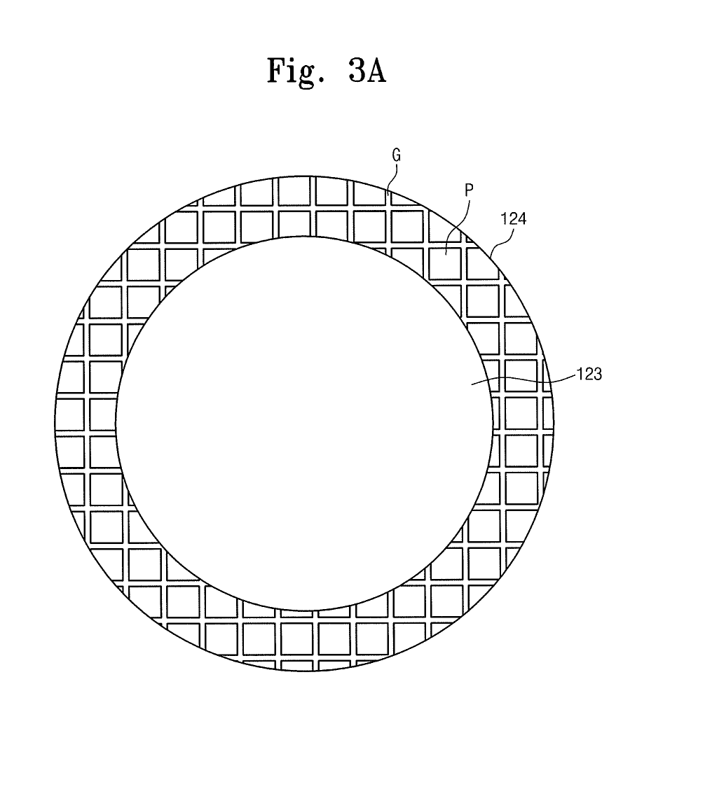

An aspect ratio of the recesses (depth/width) is set so as to not allow the dielectric substance generated during the sputtering process to be stacked in the recesses of the insulating cover 124. Thus, the dielectric substance is stacked only on the protrusions. The aspect ratio of the recesses will be described in detail below with reference to FIGS. 2A and 2B.

In general, a capacitor includes two conductors and a dielectric substance disposed between the two conductors. The capacitor has a capacitance inversely proportional to a distance between the two conductors and proportional to areas of the conductors. That is, the capacitance of the capacitor is inversely proportional to a thickness of the dielectric substance and proportional to the area of the dielectric substance.

According to the advance of the sputtering process, electric charges are accumulated on the dielectric substance stacked on the insulating cover 124. When the electric charges are accumulated on the dielectric substance, the portion of the dielectric substance in which the electric charges are accumulated may serve as a conductor.

If the insulating cover 124 were not present, the dielectric substance generated during the sputtering process could be stacked on the second supporter 122 and the electric charges could accumulate on the dielectric substance. As a result, the portion in which the electric charges are accumulated, the second supporter 122, and the dielectric substance between the portion and the second supporter 122 could form a capacitor.

On the other hand, when the insulating cover 124 is formed to cover the upper surface of the second supporter 122, the dielectric substance generated during the sputtering process is stacked on the insulating cover 124 and the electric charges are accumulated on the dielectric substance. In this case, the portion in which the electric charges are accumulated, the second supporter 122, and the dielectric substance and the insulating cover 124 between the portion and the second supporter 122 form a capacitor.

A distance between the portion in which the electric charges are accumulated and the second supporter 122, when the insulating cover 124 is not present, is greater than a distance between the portion in which the electric charges are accumulated and the second supporter 122 when the insulating cover 124 is present. As a result, the capacitance of the capacitor formed between the portion in which the electric charges are accumulated and the second supporter 122 becomes small, when the insulating cover 124 is present.

If the protrusions were not formed on the insulating cover 124, the dielectric substance generated during the sputtering process could be stacked over the entire upper surface of the insulating cover 124. In the present exemplary embodiment, however, the dielectric substance is stacked only on the protrusions and not stacked in the recesses. Thus, a contact area between the dielectric substance and the insulating cover 124 is a sum of areas of upper surfaces of the protrusions of the insulating cover 124. That is, the contact area between the dielectric substance and the insulating cover 124 may be the area of the dielectric substance that forms the capacitor.

As described above, the capacitance of the capacitor is proportional to the area of the dielectric substance. The area of the dielectric substance is reduced when the protrusions are formed on the insulating cover 124 more than if the protrusions were not formed on the insulating cover 124. The area of the dielectric substance is reduced. Accordingly, the capacitance of the capacitor formed between the second supporter 122 and the portion in which the electric charges are accumulated is reduced.

The thickness of the insulating cover 124 and sizes of the protrusions and the recesses will be described in detail with reference to FIGS. 2A and 2B below.

If the capacitance of the capacitor formed between the second supporter 122 and the portion in which the electric charges are accumulated becomes high, an arc may be easily generated. However, due to the insulating cover 124 being formed to cover the upper surface of the second supporter 122 and including the protrusions and recesses according to the present embodiment, the capacitance of the capacitor formed by the portion in which the electric charges are accumulated, the dielectric substance, and the second supporter 122 is reduced. As described above, since the capacitance of the capacitor is reduced, an arc is not easily generated.

Consequently, the sputtering apparatus may prevent an arc from being generated.

FIG. 2A is a partially enlarged view of a portion A shown in FIG. 1 and FIG. 2B is a partially enlarged view of a portion B shown in FIG. 2A.

Referring to FIGS. 2A and 2B, the insulating cover 124 is formed to cover the upper surface of the second supporter 122. The dielectric substance generated during the sputtering process is stacked on the insulating layer 124 disposed on the second supporter 122. The insulating cover 124 includes recesses G recessed downwardly from the upper surface thereof and protrusions P each of which protrudes upwardly between the recesses G. The area of the upper surface of each protrusion P may be about 68 mm² to about 1000 mm².

The depth of each recess G of the insulating layer 124 is defined by a distance between the upper surface of a corresponding protrusion of the protrusions P and a bottom surface of the recess G. The width W of each recess G of the insulating layer 124 is defined by a distance between two adjacent protrusions P.

Among parameters used in the deposition process, the aspect ratio is present. The aspect ratio represents a ratio of the depth of a recess to its width. That is, the aspect ratio is obtained by dividing the depth of the recess by the width of the recess. When the aspect ratio is relatively small, a relatively larger amount of the deposition material may be stacked in the recess. On the other hand, when the aspect ratio is relatively large, a relatively smaller amount of the deposition material is stacked in the recess.

The aspect ratio of each recess G is set so as to not allow the dielectric substance to be stacked in the recesses G. Accordingly, the dielectric substance generated during the sputtering process may not be stacked in the recesses G of the insulating cover 124. In detail, to prevent or reduce the possibility of the dielectric substance being stacked in the recesses G, the aspect ratio of each recess G may be set to be three or more. That is, the aspect ratio of each recess G may be set to allow the value obtained by dividing the depth D by the width W to be equal to or greater than three. In this case, the dielectric substance generated during the sputtering process may not be stacked in the recesses G and may be stacked only on the protrusions P of the insulating cover 124.

In general, a breakdown voltage exceeds 1000 volts when an insulating material has a thickness equal to or greater than 1 mm. Accordingly, the insulating material with a thickness greater than 1 mm may have insulating properties. Therefore, the insulating cover 124 may have a thickness H1 equal to or greater than 1 mm. For example, the thickness H1 of the insulating cover 124 may be in a range from about 2 mm to about 20 mm. The thickness H1 of the insulating cover 124 is defined by a distance between a bottom surface of the insulating cover 124 and the upper surface of the protrusions P of the insulating cover 124.

According to the advance of the sputtering process, the electric charges may accumulate on the dielectric substance stacked on the protrusions P of the insulating cover 124. When the electric charges accumulate on the dielectric substance, the portion of the dielectric substance in which the electric charges accumulate may serve as a conductor.

If the insulating cover 124 were not present, the dielectric substance generated during the sputtering process would be stacked on the second supporter 122 and the electric charges would accumulate on the dielectric substance. As a result, a capacitor would be formed between the portion in which the electric charges are accumulated and the second supporter 122 by the dielectric substance between the portion and the second supporter 122.

On the other hand, when the insulating cover 124 is formed to cover the upper surface of the second supporter 122, the dielectric substance generated during the sputtering process is stacked on the protrusions P of the insulating cover 124 and the electric charges accumulate on the dielectric substance. In this case, the capacitor is formed between the portion on which the electric charges are accumulate and the second supporter 122, separated by the dielectric substance and the insulating cover 124.

When a plurality of dielectric substances are stacked one on another, the capacitor is formed in each dielectric substance. That is, the capacitor is formed in each of the insulating cover 124 and the dielectric substance stacked on the insulating cover 124. In this case, two capacitors, which are respectively formed in the insulating cover 124 and the dielectric substance, are connected to each other in series. When the two capacitors are connected to each other in series, the total capacitance of the capacitors is decreased.

With reference to the distance, a thickness of two dielectric substances may be greater than that of one dielectric substance. That is, a sum of the thickness of the insulating cover 124 and the thickness of the dielectric substance stacked on the insulating cover 124 may be greater than a thickness of the dielectric substance stacked on the insulating cover 124. For example, the distance between the portion of the dielectric substance, in which the electric charges accumulate, and the second supporter 122 is longer when the insulating cover 124 is present than that when the insulating cover 124 is not present. Thus, the capacitance of the capacitor formed between the second supporter 122 and the portion in which the electric charges accumulate becomes smaller when the insulating cover 124 is present than that when the insulating cover 124 is not present.

If the protrusions P were not present on the insulating cover 124, the dielectric substance generated during the sputtering process could be stacked over the entire upper surface of the insulating cover 124. Thus, the contact area between the dielectric substance and the insulating cover 124 would be the entire areas of the upper surface of the insulating cover 124. The contact area between the dielectric substance and the insulating cover 124 could be the area of the dielectric substance that forms the capacitor.

In the present exemplary embodiment, on the other hand, the insulating cover 124 includes the protrusions P. The dielectric substance generated during the sputtering process is stacked only on the protrusions P and not stacked in the recesses G. Thus, the contact area between the dielectric substance stacked on the insulating cover 124 and the insulating cover 124 is the sum of the areas of the upper surfaces of the protrusions P of the insulating cover 124. That is, the area of the dielectric substance that forms the capacitor is the sum of the areas of the upper surfaces of the protrusions P of the insulating cover 124.

As described above, the capacitance of the capacitor is proportional to the area of the dielectric substance. The area of the dielectric substance that forms the capacitor is smaller when the protrusions P are formed on the insulating cover 124 than that when the protrusions P are not formed on the insulating cover 124. That is, as the number of the protrusions P increases, the area of the dielectric substance that forms the capacitor decreases.

If the capacitance of the capacitor formed between the second supporter 122 and the portion in which the electric charges are accumulated becomes high, an arc could be easily generated. However, due to the insulating cover 124 being formed to cover the upper surface of the second supporter 122 and including the protrusions P and recesses G, the capacitance of the capacitor formed by the portion in which the electric charges are accumulated, the dielectric substance, and the second supporter 122 may be reduced. Accordingly, since the capacitance of the capacitor is reduced, an arc may not be easily generated.

Consequently, the sputtering apparatus may prevent or reduce the likelihood of an arc being generated.

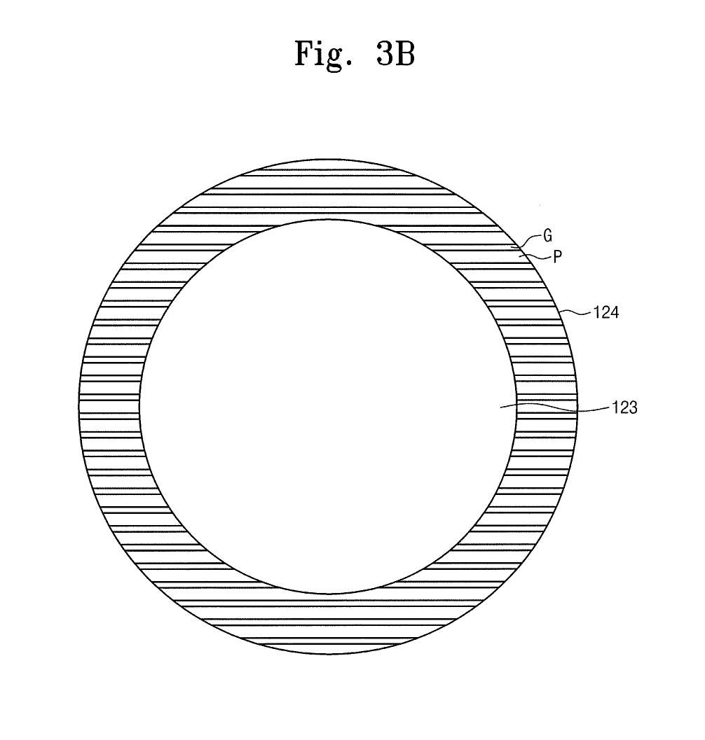

FIGS. 3A and 3B are views showing various shapes of a protruding portion shown in FIG. 2A.

Referring to FIGS. 3A and 3B, the sputtering target 123 may have a circular shape. Accordingly, the second supporter 122 has a circular shape to support a side surface of the sputtering target 123. The insulating cover 124 has a circular shape to cover the upper surface of the supporter 122.

As shown in FIG. 3A, the protrusions P may be arranged in a matrix form. The upper surface of each of the protrusions P may have an area from about 68 mm² to about 1000 mm².

As shown in FIG. 3B, the protrusions P may be formed to have a stripe shape. That is, the protrusions P may extend in a row direction. The upper surface of each of the protrusions P may have an area from about 68 mm² to about 1000 mm². Although not shown in figures, the protrusions P may be extend in a column direction.

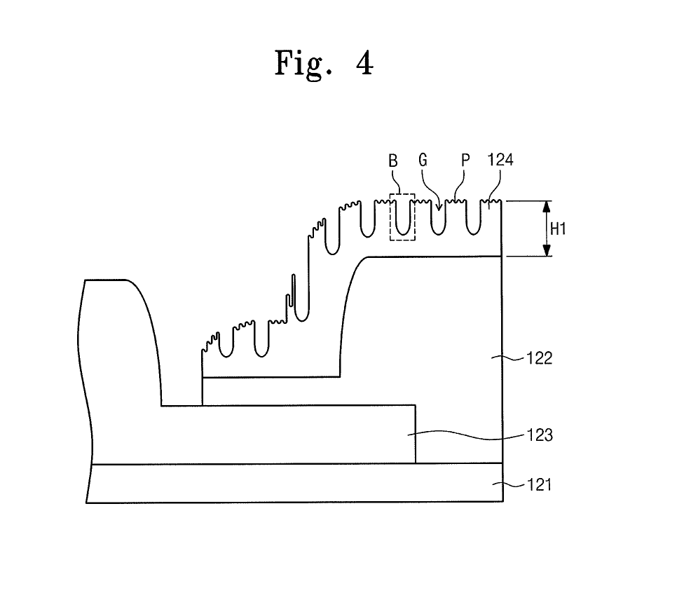

FIG. 4 is a view showing an insulating cover according to another exemplary embodiment of the present disclosure.

Referring to FIG. 4, protrusions P of an insulating layer 124 have a concavo-convex pattern. A root-mean-square (RMS) roughness of the concavo-convex pattern may be greater than 1 μm.

The RMS roughness represents the degree of the concavo-convex pattern of the surface, e.g., the degree of the roughness. A cross-section of the concavo-convex pattern may be represented by a curve (hereinafter, referred to as an RMS roughness curve). A difference between a lowermost portion of the RMS roughness curve and an uppermost portion of the RMS roughness curve is defined as a maximum roughness (Rmax). In addition, the RMS roughness may be represented by an average of absolute values of both side heights at an RMS centerline that indicates root-mean-square average of the RMS roughness.

The concavo-convex pattern on the upper surface of the protrusions P may be formed in various ways. For instance, after the insulating cover 124 is formed, the concavo-convex pattern is formed by colliding small particles having greater strength than the insulating cover 124 with the surface of the insulating cover 124. In other implementations, the concavo-convex pattern may be formed by thermal spray coating an insulating material on the surface of the insulating cover 124. The thermal spray coating is a surface treatment method that melts a coating material using heat, electrical arc, or plasma, sprays the melted coating material with a high speed onto a target material to be collided with the target, so that the surface of the target is coated with the coating material. Thus, the concavo-convex pattern is formed on the upper surface of the insulating cover 124 and the protrusions P and the recesses G are formed through the above mentioned methods.

When the upper surface of the protrusions P of the insulating cover 124 has the concavo-convex pattern, an adhesive force between the dielectric substance stacked on the upper surface of the protrusions P and the insulating cover 124 may be improved more than if the upper surface of the protrusions P of the insulating cover 124 were to be smooth. As described above, the dielectric substance generated during the sputtering process and the insulating cover 124 formed of the dielectric substance may have the same thermal expansion rate. Accordingly, the dielectric substance stacked on the insulating cover 124 is not likely to be dropped onto the sputtering target 123. In addition, when the upper surface of the protrusions P of the insulating cover 124 has the concavo-convex pattern, it is more difficult for the dielectric substance stacked on the insulating cover 124 to be dropped onto the sputtering target 123.

By way of summation and review, during a sputtering process, a dielectric substance is generated. The dielectric substance may be stacked on a supporter, e.g., a clamp, supporting the sputtering target. The supporter applies a voltage provided from a voltage supply to the sputtering target. When the dielectric substance is stacked on the supporter, an arc could occur due to electric charges on the dielectric substance. Consequently, the sputtering target could be damaged by the arc.

In contrast, the sputtering apparatus according to embodiments may prevent an arc from occurring.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A sputtering apparatus, comprising:
a substrate;
a sputtering target disposed to face the substrate and including a sputtering material to be deposited on the substrate, the sputtering target colliding with an ionized gas particle such that the sputtering material is separated from the sputtering target by the collision of the ionized gas particle with the sputtering target and the sputtering material is deposited on the substrate;
a supporter that supports a lower surface and a side surface of the sputtering target; and
an insulating cover that covers an upper surface of the supporter supporting the side surface of the sputtering target, the insulating cover including:
a plurality of recesses recessed downwardly from an upper surface of the insulating cover; and
a plurality of protrusions protruding upwardly between the recesses.

2. The sputtering apparatus of claim 1, wherein the supporter includes:
a first supporter attached to the lower surface of the sputtering target to support the sputtering target, and
a second supporter attached to the side surface and upper peripheral surfaces of the sputtering target to support the sputtering target, the insulating cover covering an upper surface of the second supporter.

3. The sputtering apparatus of claim 1, wherein the insulating cover includes a dielectric material.

4. The sputtering apparatus of claim 1, wherein an upper surface of each of the protrusions has an area from about 68 mm² to about 1000 mm².

5. The sputtering apparatus of claim 4, wherein the protrusions are arranged in a matrix form.

6. The sputtering apparatus of claim 4, wherein the protrusions extend in a row direction to have a stripe shape.

7. The sputtering apparatus of claim 1, wherein an aspect ratio defined by a depth and a width of each of the recesses is equal to or greater than 3.

8. The sputtering apparatus of claim 1, wherein the insulating cover has a thickness of about 2 mm to about 20 mm, the thickness being a distance between a lower surface of the insulating cover and an upper surface of the insulating cover.

9. The sputtering apparatus of claim 1, wherein each of the protrusions has a concavo-convex pattern.

10. The sputtering apparatus of claim 9, wherein a root-mean-square roughness of the concavo-convex pattern is greater than about 1 micrometer.

11. The sputtering apparatus of claim 1, further comprising:
a power supply part that applies a negative voltage to the sputtering target; and
a gas supply part that provides the gas particle, wherein the gas particle collides with an electron discharged from the sputtering target to be ionized and the ionized gas particle collides with the sputtering target.
